(19) United States
(12) Patent Application Publication
(10) Pub. No.: US 2015/0035148 A1
(43) Pub. Date: Feb. 5, 2015

(54) SEMICONDUCTOR PACKAGES AND METHODS OF FABRICATING THE SAME

(71) Applicants: Heeseok LEE, Yongin-si (KR); Yoonha JUNG, Suwon-si (KR); Jongkook KIM, Hwaseong-si (KR); Eun-Hee JUNG, Hwaseong-si (KR)

(72) Inventors: Heeseok LEE, Yongin-si (KR); Yoonha JUNG, Suwon-si (KR); Jongkook KIM, Hwaseong-si (KR); Eun-Hee JUNG, Hwaseong-si (KR)

(21) Appl. No.: 14/291,883

(22) Filed: May 30, 2014

(30) Foreign Application Priority Data
Jul. 30, 2013 (KR) 10-2013-0090268

(51) Int. Cl. H01L 23/00; H01L 23/498

(52) U.S. Cl. CPC H01L 24/14; H01L 24/81; H01L 23/49816; H01L 23/49827
USPC 257/738; 438/107

(57) ABSTRACT

A semiconductor package including a lower package including a lower package substrate and a lower semiconductor chip, the lower package substrate including an interconnection part and a core part, the core part including connection vias exposed by openings, the lower semiconductor chip buried in the core part, an upper package including an upper package substrate, an upper semiconductor chip provided on the upper package substrate, and solder balls provided on a bottom surface of the upper package substrate, and an intermetallic compound layer at an interface between the connection vias and the solder balls in the openings may be provided.

### CROSS-REFERENCE TO RELATED APPLICATIONS

This U.S. non-provisional patent application claims priority under 35 U.S.C. §119 to Korean Patent Application No. 10-2013-0090268, filed on Jul. 30, 2013, in the Korean Intellectual Property Office, the entire contents of which are hereby incorporated by reference.

### BACKGROUND OF THE INVENTION

Example embodiments of the inventive concepts relate to semiconductor packages and/or methods of fabricating the same, and in particular, to semiconductor packages having improved electric characteristics and/or methods of fabricating the same.

There is an increasing need for semiconductor-based electronic products with high performance, small thickness, and small size. To meet this need, various package technologies have been developed in the semiconductor industry. For example, a package including a plurality of semiconductor chips is recently developed. This makes it possible to realize various functions and/or high density, compared with the conventional package including a single semiconductor chip.

To realize a high-density package with a plurality of stacked semiconductor chips, there has been suggested a package-on-package (POP) structure, in which a package is stacked on another package. In the case of the POP structure, since each of semiconductor packages therein is a test-passed product, it is possible to reduce a probability of failure at final stage. The use of the POP-type semiconductor package allows portable or mobile electronic devices to have a reduced size and various functions.

### SUMMARY

Some example embodiments of the inventive concepts provide semiconductor packages with improved electric characteristics.

Some example embodiments of the inventive concepts provide methods of fabricating semiconductor packages with improved electric characteristics.

According to an example embodiment of the inventive concepts, a semiconductor package includes a lower package including a lower package substrate and a lower semiconductor chip, the lower package substrate including an interconnection part and a core part stacked on the interconnection part, the core part including connection vias exposed by openings defined therein, the lower semiconductor chip buried in the core part, an upper package including an upper package substrate, an upper semiconductor chip provided on the upper package substrate, and solder balls provided on a bottom surface of the upper package substrate, and an intermetallic compound layer interposed at an interface between the connection vias and the solder balls in the openings.

In some example embodiments, the interconnection part may include a plurality of insulating layers and internal wires provided therebetween, and the internal wires may electrically connect the lower package substrate to the connection vias.

In some example embodiments, the semiconductor package may further include chip vias buried in the core part and be configured to electrically connect the internal wires electrically to the lower semiconductor chip.

In some example embodiments, the internal wires and the connection vias may include a same material.

In some example embodiments, the solder balls and the connection vias may include metal materials different from each other.

In some example embodiments, the intermetallic compound layer may include at least one of Sn—Ag—Cu, SnCu, AgCu, or Sn—Pb—Cu.

In some example embodiments, the connection vias may be at least partially disposed in the openings and joined with the solder balls.

In some example embodiments, the solder balls may be in contact with sidewalls of the openings, respectively.

In some example embodiments, the solder balls may be spaced apart from sidewalls of the openings.

According to an example embodiment of the inventive concepts, a method of fabricating a semiconductor package includes providing a lower package substrate, in which an interconnection part and a core part are sequentially provided, the interconnection part including internal wires and the core part including connection vias buried therein and connected to the internal wires, performing a laser drilling process on the core part of the lower package substrate to form openings exposing the connection vias, preparing an upper package substrate, on which an upper semiconductor chip and solder balls are attached, disposing the upper package substrate on the lower package substrate such that the solder balls are provided in the openings, and then joining the solder balls to the connection vias using a reflow process.

In some example embodiments, the joining the solder balls to the connection vias may include forming an intermetallic compound layer at an interface between the solder balls and the connection vias, using an inter-diffusion of metallic elements contained in the solder balls and the connection vias.

In some example embodiments, the solder balls may include at least one of tin (Sn), silver (Ag), tin-lead (SnPb) alloy, or tin-silver (SnAg) alloy.

In some example embodiments, the connection vias may include a copper-containing layer.

In some example embodiments, the intermetallic compound layer may include at least one of Sn—Ag—Cu, SnCu, AgCu, or Sn—Pb—Cu.

In some example embodiments, the method may further include recessing a top surface of the core part to form a chip hole, mounting a lower semiconductor chip in the chip hole, and forming an insulating cover on a top surface of the core part to cover the lower semiconductor chip, before the forming of the openings.

According to an example embodiment of the inventive concepts, a semiconductor package includes a solder ball on a first semiconductor package, a connection via on a second semiconductor package and projecting into the solder ball, and an intermetallic compound layer at an interface between the solder ball and the connection via.

The first semiconductor package may include a first package substrate, the first package substrate may include an opening, and the connection via and at least a portion of the solder ball disposed in the opening.

The intermetallic compound layer may be provided along an entire exposed surface of the connection via in the opening.

The solder ball may be configured to completely fill a remaining space of the opening above the connection via.

The solder ball may be spaced apart from a sidewall of the opening.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a sectional view illustrating a semiconductor package according to a first example embodiment of the inventive concepts.

FIG. 2 is a sectional view illustrating a semiconductor package according to a second example embodiment of the inventive concepts.

FIG. 3 is a sectional view illustrating a semiconductor package according to a third example embodiment of the inventive concepts.

FIG. 4 is a sectional view illustrating a semiconductor package according to a fourth example embodiment of the inventive concepts.

FIGS. 5A through 5E are sectional views illustrating a method of fabricating a semiconductor package according to an example embodiment of the inventive concepts.

FIG. 6 is a block diagram illustrating an example of electronic systems including semiconductor packages according to the embodiments of the inventive concept.

FIG. 7 is a block diagram illustrating an example of memory systems including semiconductor packages according to an example embodiment of the inventive concepts.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given example embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which some example embodiments are shown. Example embodiments of the inventive concepts may, however, be embodied in many different forms and should not be construed as being limited to the example embodiments set forth herein; rather, these example embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

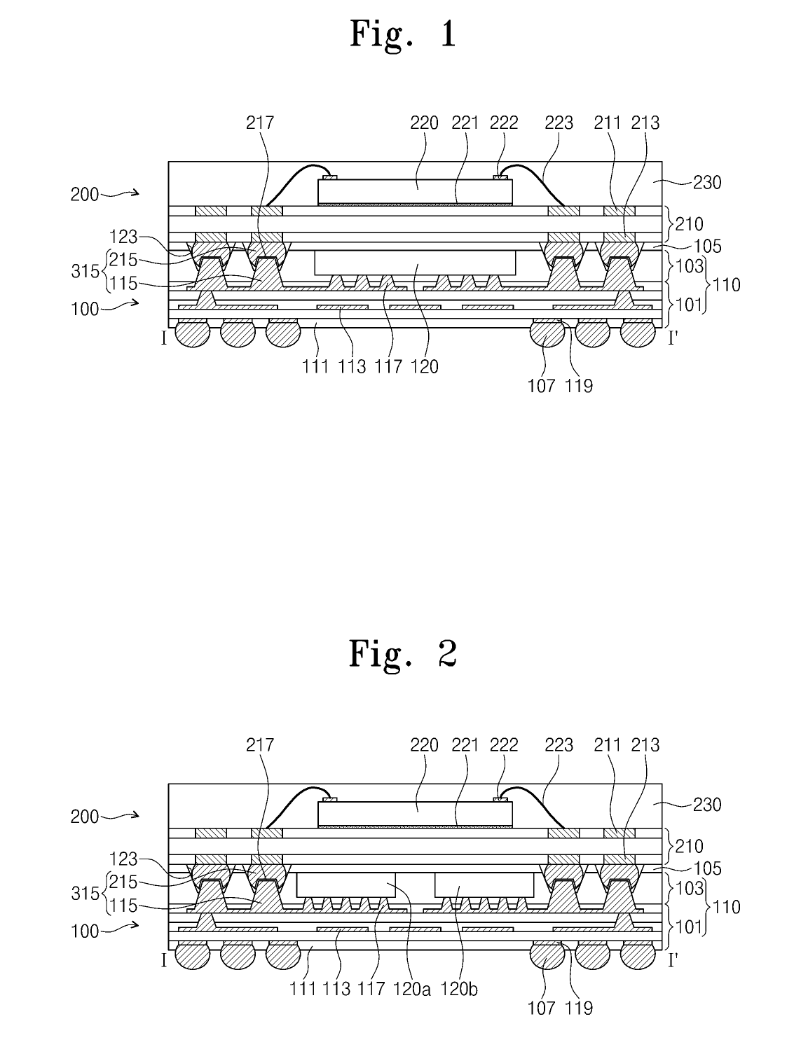

FIGS. 1 through 3 are sectional views illustrating semiconductor packages according to first, second, and third example embodiments, respectively, of the inventive concepts.

Referring to FIG. 1, a lower package 100 includes a lower package substrate 110 and a lower semiconductor chip 120 buried in the lower package substrate 110.

The lower package substrate 110 may be a printed circuit board (PCB) having a multi-layered structure. The lower package substrate 110 may include an interconnection part 101 and a core part 103. The interconnection part 101 may include insulating layers 111 and internal wires 113, which are provided in a multi-layered structure. The core part 103 may be disposed on the interconnection part 101. Connection vias 115 and chip vias 117 may be buried in the core part 103 and be connected to the internal wires 113. The connection vias 115 may be provided in an edge region of the lower package substrate 110, while the chip vias 117 may be provided between the connection vias 115 or in a central region of the lower package substrate 110. The connection vias 115 may be provided to have top surfaces that are higher than those of the chip vias 117. For example, the top surfaces of the connection vias 115 may be positioned more adjacent to a top surface of the core part 103, compared with top surfaces of the chip vias 117. The connection vias 115 may include a copper-containing layer. The internal wires 113, the connection vias 115, and the chip vias 117 may be formed of a same material. The core part 103 may be formed to have openings 123. The openings 123 may be formed to expose upper portions of the connection vias 115.

The lower semiconductor chip 120 may be provided at or buried in the core part 103. The lower semiconductor chip 120 may be in contact with and electrically connected to the chip vias 117. In some example embodiments, the lower semiconductor chip 120 may be, for example, a logic device (e.g., a micro-processor) or a memory device. In other example embodiments, the lower semiconductor chip 120 may include both a memory device and a logic device. Further, an insulating cover 105 may be provided on the core part 103.

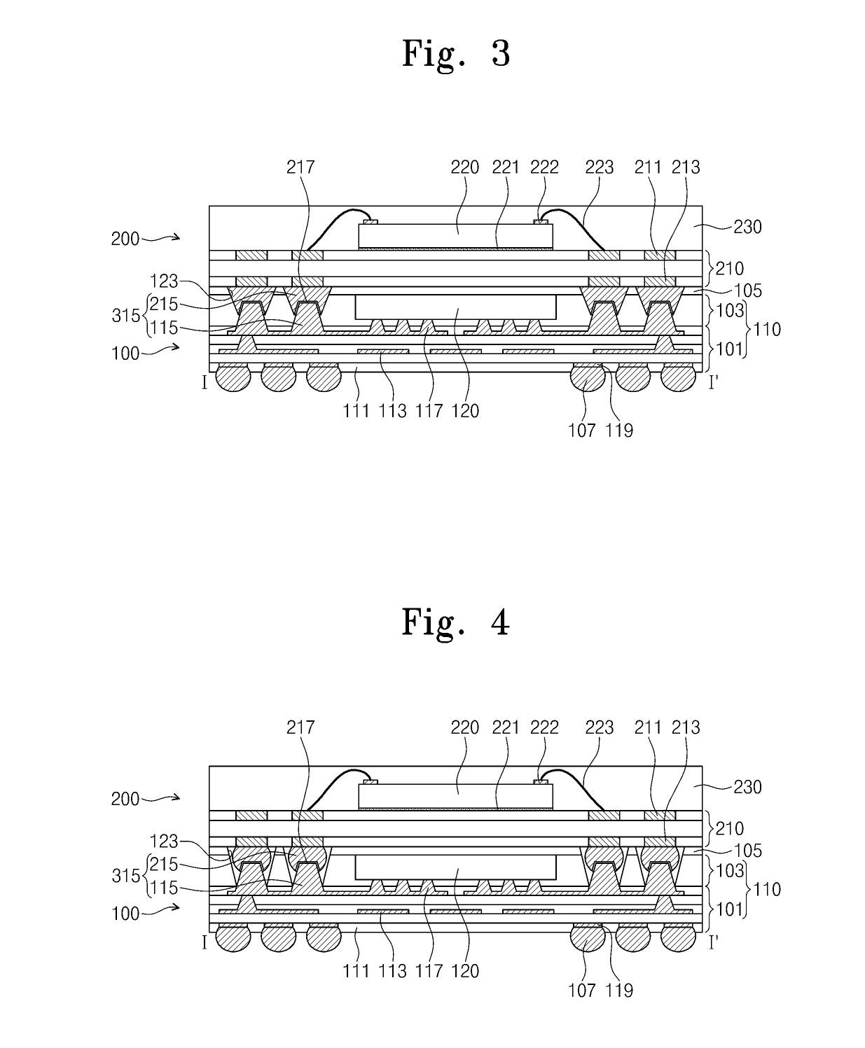

According to a second example embodiment of the inventive concepts, as shown in FIG. 2, a first lower semiconductor chip 120a and a second lower semiconductor chip 120b are provided at or buried in the core part 103.

Outer terminal pads 119 are provided on a bottom surface of the lower package substrate 110, and outer terminals 107 are attached on the outer terminal pads 119. The outer terminals 107 may electrically connect the semiconductor package to an external device.

An upper package 200 includes an upper package substrate 210, an upper semiconductor chip 220, and a molding layer 230 covering the upper semiconductor chip 220. The upper package 200 is stacked on the lower package 100.

The upper package substrate 210 may be a printed circuit board (PCB). Similar to the lower package substrate 110, the upper package substrate 210 may include a plurality of stacked insulating layers (not shown) and internal wires (not shown) provided between the insulating layers. A wire pad 211 may be provided on a top surface of the upper package substrate 210. Solder pads 213 may be provided on a bottom surface of the upper package substrate 210.

The upper semiconductor chip 220 is provided on the upper package substrate 210. The upper semiconductor chip 220 is attached to the top surface of the upper package substrate 210 by an adhesive layer 221. In some example embodiments, the upper semiconductor chip 220 may be, for example, a logic device (e.g., a micro-processor) or a memory device. In other example embodiments, the upper semiconductor chip 220 may include both a memory device and a logic device. A bonding pad 222 may be provided on the upper semiconductor chip 220. The bonding wire 223 may connect the bonding pad 222 to the wire pad 211 through a bonding wire 223. Accordingly, the bonding wire 223 may electrically connect the upper semiconductor chip 220 to the upper package substrate 210 through the bonding wire 223.

Solder balls 215 are attached to the solder pads 213. The solder balls 215 may be formed of a different material from the connection vias 115. The solder balls 215 may include, for example, tin (Sn), silver (Ag), tin-lead (SnPb) alloy, or tin-silver (SnAg) alloy. The solder balls 215 are provided in openings 123 of the lower package substrate 110 and thereby be coupled to the connection vias 115. For example, the connection vias 115 may be partially inserted into the solder balls 215 and be joined or coupled with the solder balls 215. The solder balls 215 and the connection vias 115 joined with each other may constitute a conductive connecting portion 315. The solder balls 215 may be joined or coupled with an upper portion of the connection vias 115. The solder balls 215 may not completely fill the openings 123. Accordingly, sidewalls of the openings 123 may be partially exposed.

An intermetallic compound layer (IMC) 217 may be formed between the connection vias 115 and the solder balls 215. The IMC 217 may be partially formed on a surface of the connection vias 115 in contact with the solder balls 215. The IMC 217 may include Sn—Ag—Cu, SnCu, AgCu, or Sn—Pb—Cu.

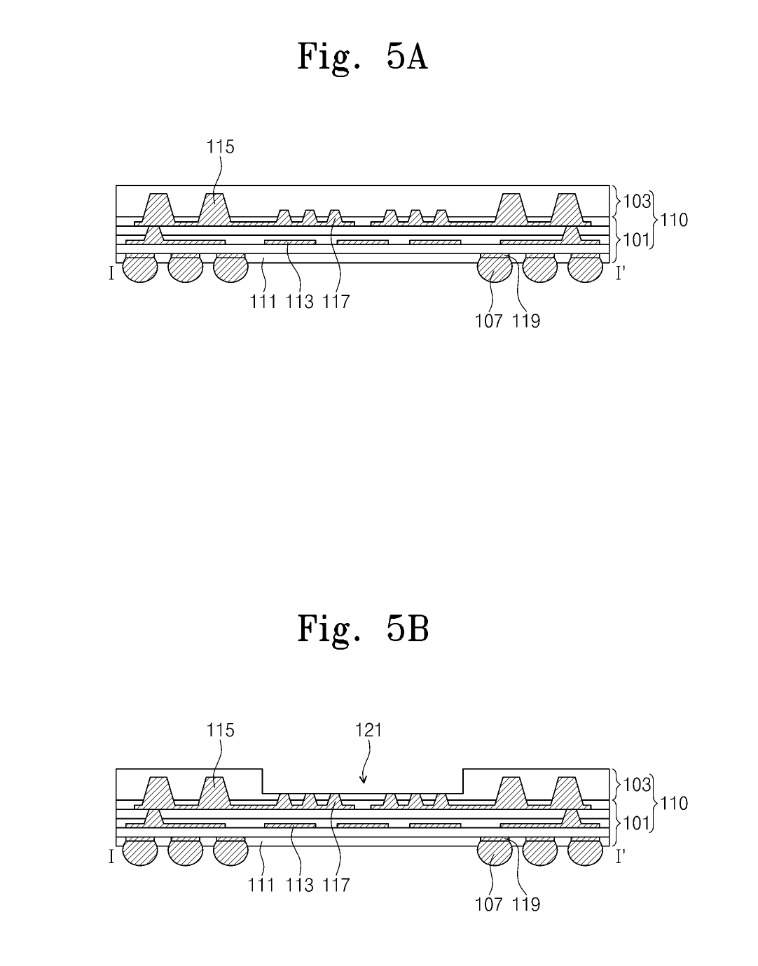

According to a third example embodiment of the inventive concepts, as shown in FIG. 3, the solder balls 215 completely fill the openings 123, and thus are joined or coupled with the connection vias 115. Accordingly, the IMC 217 may cover entire surfaces of the connection vias 115 exposed by the openings 123.

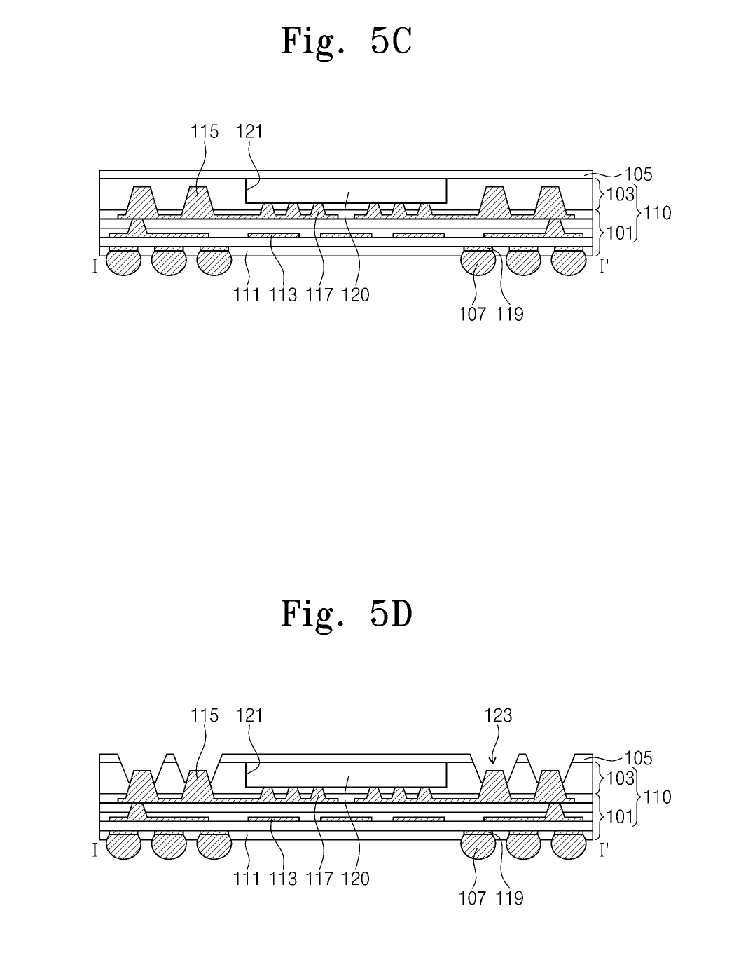

FIG. 4 is a sectional view illustrating a semiconductor package according to a fourth example embodiment of the inventive concepts. In the following description of FIG. 4, previously described elements are identified by similar or identical reference numbers without repeating an overlapping description thereof, for the sake of brevity.

Referring to FIG. 4, the openings 123 is formed to completely penetrate the core part 103. Accordingly, the connection vias 115 in the core part 103 may be fully exposed through the openings 123. The solder balls 215 are provided spaced apart from the sidewalls of the openings 123 and are joined or coupled to the connection vias 115.

Similar to the third example embodiment, the solder balls 215 may be formed to completely fill the opening 123, and the IMC 217 may be formed to cover entire exposed surfaces of the connection vias 115.

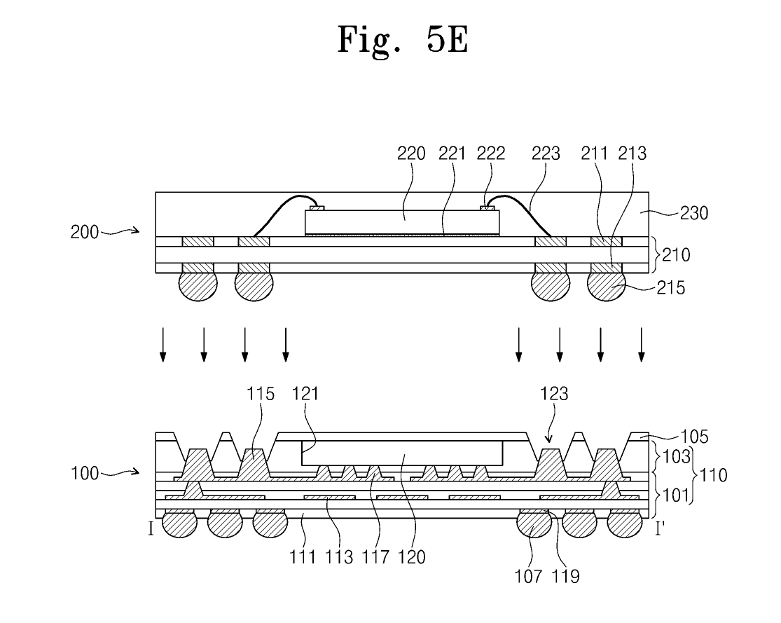

FIGS. 5A through 5E are sectional views illustrating a method of fabricating a semiconductor package according to example embodiments of the inventive concepts.

Referring to FIG. 5A, the lower package substrate 110 may be prepared. The lower package substrate 110 may be a printed circuit board (PCB). The lower package substrate 110 may include the interconnection part 101 and the core part 103. The core part 103 may be disposed on the interconnection part 101.

The interconnection part 101 may include the insulating layers 111 and the internal wires 113 that are provided in a multi-layered structure. The core part 103 may be formed of epoxy molding compound (EMC). The connection vias 115 and the chip vias 117 may be formed at least partially in the interconnection part 101. The connection vias 115 and the chip vias 117 may be connected to the internal wires 113 and be buried or provided in the core part 103. The connection vias 115 may be formed in an edge region of the lower package substrate 110, while the chip vias 117 may be provided between the connection vias 115 or at a central region of the lower package substrate 110. The connection vias 115 may be formed to have top surfaces that are higher than those of the chip vias 117, and are positioned adjacent to the top surface of the core part 103. The connection vias 115 may be formed of, for example, a copper-containing layer. The internal wires 113, the connection vias 115, and the chip vias 117 may be formed of a same material.

The outer terminal pads 119 may be formed on a bottom surface of the lower package substrate 110, and the outer terminals 107 may be attached on the outer terminal pads 119. In other example embodiments, the outer terminals 107 may be formed after a process of stacking the lower and upper packages 100 and 200 (as shown in FIG. 1) is complete.

Referring to FIG. 5B, a top surface of the core part 103 may be partially recessed to form a chip hole 121. The chip hole 121 may be formed to expose top surfaces of the chip vias 117.

Referring to FIG. 5C, the lower semiconductor chip 120 may be mounted in the chip hole 121. The lower semiconductor chip 120 may be formed to have a thickness that is equivalent to or smaller than a depth of the chip hole 121. In certain example embodiments, a backside polishing process may be performed to a bottom surface of the lower semiconductor chip 120 such that the lower semiconductor chip 120 can have a reduced thickness.

Further, the insulating cover 105 may be formed on the core part 103, which are provided with the lower semiconductor chip 120. The insulating cover 105 may be formed to cover the top surface of the lower semiconductor chip 120, and thus, the lower semiconductor chip 120 may be buried in the core part 103.

Referring to FIG. 5D, a laser drilling process may be performed to the insulating cover 105. As the result of the laser drilling process, the openings 123 may be formed in the core part 103. The openings 123 may be formed to expose the upper portion of the connection vias 115.

In other example embodiments, as shown in FIG. 4, the laser drilling process may be performed such that the openings 123 are formed to expose the connection vias 115 buried in the core part 103. Accordingly, the connection vias 115 may have at least portions protruding from bottoms of the openings 123.

Referring to FIG. 5E, one of the lower and upper packages 100 and 200 may be disposed adjacent to the other and then be joined with the other. For example, the upper package 200 may be stacked or mounted on the lower package 100.

The upper package 200 may be formed to include the upper package substrate 210 and the upper semiconductor chip 220, which is attached to the top surface of the upper package substrate 210 by the adhesive layer 221. The wire pads 211 may be formed on the top surface of the upper package substrate 210. The bonding wires 223 may connect the wire pads 211 to the bonding pads 222 disposed on the upper semiconductor chip 220. Thus, the upper semiconductor chip 220 may be electrically connected to the upper package substrate 210. The solder pads 213 may be formed on the bottom surface of the upper package substrate 210. The solder balls 215 may be attached to the solder pads 213, respectively.

The upper package 200 may be stacked on the lower package 100 such that the solder balls 215 are inserted into the openings 123. The solder balls 215 may include, for example, tin (Sn), silver (Ag), tin-lead (SnPb) alloy, or tin-silver (SnAg) alloy.

To join or couple the solder balls 215 to the connection vias 115, a reflow process may be performed to the solder balls 215. In the reflow process, the solder balls 215 may be heated and melted, thereby being joined to the connection vias 115. Accordingly, as shown in FIGS. 1, 3, and 4, the solder balls 215 and the connection vias 115 may be joined to form the conductive connecting portion 315.

The IMC 217 may be formed on a surface of the connection vias 115 in contact with the solder balls 215. The IMC 217 may be formed as the result of inter-diffusion between at least two different metals. For example, during the reflow process, at least two different metallic elements contained in the solder balls 215 and the connection vias 115 may be inter-diffused to form the intermetallic compound layer 217. The intermetallic compound layer 217 may include, for example, Sn—Ag—Cu, SnCu, AgCu, or Sn—Pb—Cu.

Referring back to FIG. 1, in the case where each of the solder balls 215 has less volume than a corresponding one of the openings 123, each of the solder balls 215 may partially fill the corresponding one of the openings 123, while maintaining its original shape. Accordingly, the solder balls 215 joined to the connection vias 115 may be in contact with the sidewalls of the openings 123, respectively.

Alternatively, referring back to FIG. 4, in the case where each of the solder balls 215 has much less volume than a corresponding one of the openings 123, the solder balls 215 joined or coupled to the connection vias 115 may be formed spaced apart from the sidewalls of the openings 123, respectively.

By contrast, referring back to FIG. 3, in the case where each of the solder balls 215 has a same volume as a corresponding one of the openings 123, each of the solder balls 215, which are joined or coupled to the connection vias 115, may be formed to entirely fill the corresponding one of the openings 123. Accordingly, the IMC 217 may be formed on the entire surfaces of the connection vias 115 exposed by the openings 123.

Even if there is non-uniformity in a fabrication process, in each semiconductor package, the conductive connecting portion 315 may have one of structures depicted in FIGS. 1 and 3, and the openings 123 may have one of structures depicted in FIGS. 1 and 4.

The lower package 100 and the upper package 200 may be physically joined to each other by the conductive connecting portion 315, thereby being electrically connected to each other. The upper package 200 stacked on the lower package 100 may form a package-on-package structure.

According to some example embodiments of the inventive concepts, the connection vias 115 buried in the lower package substrate 110 may be exposed by using the laser drilling process, and then, be joined with the solder balls 215 of the upper package substrate 210 to form the conductive connecting portion 315. Instead of solder balls or through vias, the connection vias 115 provided on the lower package substrate 110 are used to connect the lower package 100 to the upper package 200. Thus, a fabrication process may be simplified. Further, because the connection vias 115 have an aspect ratio larger than the conventional solder balls provided on the lower package substrate 110, the connection vias 115 may be connected to the solder balls 215 of the upper package 200 with an increased contact area. Accordingly, joint stability between the lower package 100 and the upper package 200 may be enhanced, and intervals between the connection vias 115 and the openings 123 may be reduced. Accordingly, the number of the conductive connecting portions 315 in a given area may be increased, and thus an effective contact area between the upper and lower packages 100 and 200 can be increased.

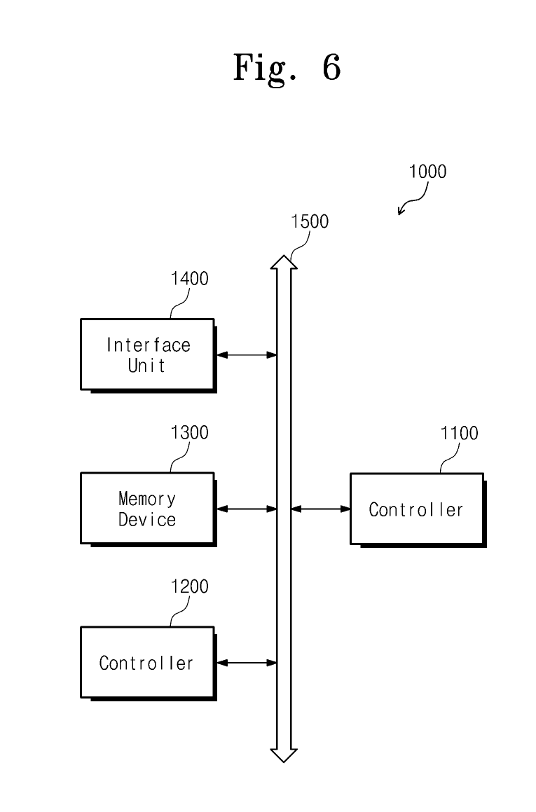

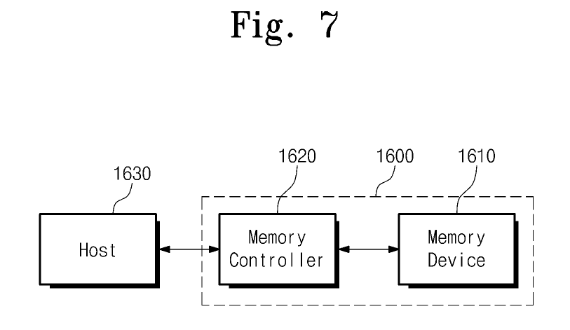

FIG. 6 is a block diagram illustrating an example of an electronic system including semiconductor packages according to some example embodiments of the inventive concepts. FIG. 7 is a block diagram illustrating an example of a memory system including semiconductor packages according to some example embodiments of the inventive concepts.

Referring to FIG. 6, an electronic system 1000 according to an example embodiment includes a controller 1100, an input/output (I/O) device 1200, a memory device 1300 and a data bus 1500. At least two of the controller 1100, the I/O device 1200 and the memory device 1300 may communicate with each other through the data bus 1500. The data bus 1500 may correspond to a path through which electrical signals are transmitted. The controller 1100 may include, for example, at least one of a microprocessor, a digital signal processor, a microcontroller and a logic device. The logic device may have a similar function to any one of the microprocessor, the digital signal processor and the microcontroller. The controller 1100 and/or the memory device 1300 may include at least one of the semiconductor packages described in the above example embodiments. The I/O device 1200 may include at least one of a keypad, a keyboard and a display device. The memory device 1300 may store data and/or commands executed by the controller 1100. The memory device 1300 may include, for example, a volatile memory device and/or a nonvolatile memory device. For example, the memory device 1300 may include a flash memory device to which the package techniques according to some example embodiments are applied. The flash memory device may constitute a solid state disk (SSD). In this case, the solid state disk including the flash memory device may stably store a large capacity of data. The electronic system 1000 may further include an interface unit 1400. The interface unit 1400 may transmit data to a communication network or may receive data from a communication network. The interface unit 1400 may operate wirelessly or through cable. For example, the interface unit 1400 may include an antenna for wireless communication or a transceiver for cable communication. Although not shown in the drawings, the electronic system 1000 may further include an application chipset and/or a camera image sensor.

The electronic system 1000 may be realized as, for example, a mobile system, a personal computer, an industrial computer, or a logic system performing various functions. For example, the mobile system may be one of a personal digital assistant (PDA), a portable computer, a web tablet, a wireless phone, a mobile phone, a laptop computer, a digital music system, and an information transmit/receive system. When the electronic system 1000 performs wireless communication, the electronic system 1000 may be used in a communication interface protocol of a communication system, for example, CDMA, GSM, NADC, E-TDMA, WCDMA, CDMA2000, Wi-Fi, Muni Wi-Fi, Bluetooth, DECT, Wireless USB, Flash-OFDM, IEEE 802.20, GPRS, iBurst, WiBro, WiMAX, WiMAX-Advanced, UMTS-TDD, HSPA, EVDO, LTE-Advanced, or MMDS.

Referring to FIG. 7, a memory card 1600 may include a non-volatile memory device 1610 and a memory controller 1620. The non-volatile memory device 1610 and the memory controller 1620 may store data or read stored data. The non-volatile memory device 1610 may include, for example, at least one non-volatile memory device, to which the semiconductor package technology according to example embodiments of the inventive concept is applied. The memory controller 1620 may control the non-volatile memory device 1610 in order to read the stored data and/or to store data in response to read/write requests of a host 1630.

According to example embodiments of the inventive concepts, the semiconductor packages may include a conductive connecting portion formed by joining a connection via, which is buried in a lower package substrate, to a solder ball of an upper package substrate. Because the connection vias so formed may have a high aspect ratio, the connection via may be connected to the solder ball with an increased contact area, and thus reduce a distance between the conductive connecting portions can be effectively reduced. Accordingly, the number of the conductive connecting portions may be increased, and thus an effective contact area between the upper and lower packages for an electric connection may be increased.

While some example embodiments of the inventive concepts have been particularly shown and described, it will be understood by one of ordinary skill in the art that variations in form and detail may be made therein without departing from the spirit and scope of the attached claims.

What is claimed is:

1. A semiconductor package, comprising:
a lower package including a lower package substrate and a lower semiconductor chip, the lower package substrate including an interconnection part and a core part stacked on the interconnection part, the core part including connection vias exposed by openings defined therein, the lower semiconductor chip buried in the core part;
an upper package including an upper package substrate, an upper semiconductor chip on the upper package substrate, and solder balls on a bottom surface of the upper package substrate; and
an intermetallic compound layer at an interface between the connection vias and the solder balls in the openings.

2. The semiconductor package of claim 1, wherein the interconnection part includes a plurality of insulating layers and internal wires provided therebetween, and the internal wires electrically connect the lower package substrate to the connection vias.

3. The semiconductor package of claim 2, further comprising:
chip vias buried in the core part, the chip vias configured to electrically connect the internal wires to the lower semiconductor chip.

4. The semiconductor package of claim 2, wherein the internal wires and the connection vias include a same material.

5. The semiconductor package of claim 1, wherein the solder balls and the connection vias include metal materials different from each other.

6. The semiconductor package of claim 5, wherein the intermetallic compound layer includes at least one of Sn—Ag—Cu, SnCu, AgCu, and Sn—Pb—Cu.

7. The semiconductor package of claim 1, wherein the connection vias are at least partially disposed in the openings and are joined with the solder balls.

8. The semiconductor package of claim 1, wherein the solder balls are in contact with sidewalls of the openings, respectively.

9. The semiconductor package of claim 1, wherein the solder balls are spaced apart from sidewalls of the openings.

10. A method of fabricating a semiconductor package, comprising:
providing a lower package substrate, in which an interconnection part and a core part are sequentially provided, the interconnection part including internal wires and the core part including connection vias buried therein and connected to the internal wires;
performing a laser drilling process on the core part of the lower package substrate to form openings exposing the connection vias;
preparing an upper package substrate, on which an upper semiconductor chip and solder balls are attached;
disposing the upper package substrate on the lower package substrate such that the solder balls are provided in the openings; and
joining the solder balls to the connection vias using a reflow process.

11. The method of claim 10, wherein the joining the solder balls to the connection vias includes forming an intermetallic compound layer at an interface between the solder balls and the connection vias.

12. The method of claim 11, wherein the solder balls include at least one of tin (Sn), silver (Ag), tin-lead (SnPb) alloy, or tin-silver (SnAg) alloy.

13. The method of claim 11, wherein the connection vias include a copper-containing layer.

14. The method of claim 11, wherein the intermetallic compound layer includes at least one of Sn—Ag—Cu, SnCu, AgCu, or Sn—Pb—Cu.

15. The method of claim 10, before the forming of the openings, further comprising:
recessing a top surface of the core part to form a chip hole;
mounting a lower semiconductor chip in the chip hole; and
forming an insulating cover on the top surface of the core part to cover the lower semiconductor chip.

16. A semiconductor package, comprising:
a solder ball on a first semiconductor package;
a connection via on a second semiconductor package and projecting into the solder ball; and
an intermetallic compound layer at an interface between the solder ball and the connection via.

17. The semiconductor package of claim 16, wherein the second semiconductor package includes a second package substrate, the second package substrate includes an opening, and the connection via and at least a portion of the solder ball disposed in the opening.

18. The semiconductor package of claim 17, wherein the intermetallic compound layer is provided along an entire exposed surface of the connection via in the opening.

19. The semiconductor package of claim 17, wherein the solder ball is configured to completely fill a remaining space of the opening above the connection via.

20. The semiconductor package of claim 17, wherein the solder ball is spaced apart from a sidewall of the opening.
